(19) United States
(12) Patent Application Publication
(10) Pub. No.: US 2026/0194365 A1
(43) Pub. Date: Jul. 9, 2026

(54) METHOD FOR OPERATING A MEMS SENSOR SYSTEM AND MEMS SENSOR SYSTEM

(71) Applicant: Robert Bosch GmbH, Stuttgart (DE)

(72) Inventors: Jeffrey Gregory, Reutlingen (DE); Clemens Jurgschat, Ehningen (DE); Shang-Chun Lin, Reutlingen (DE)

(21) Appl. No.: 19/391,039

(22) Filed: Nov. 17, 2025

(30) Foreign Application Priority Data
Jan. 9, 2025 (DE) 10 2025 100 525.7

(51) Int. Cl. G01C 25/00; G01C 19/5776

(52) U.S. Cl. CPC G01C 25/00; G01C 19/5776

(57) ABSTRACT

A method for operating a MEMS sensor system having at least one ASIC structure, a MEMS structure, and a stress sensor formed on the ASIC structure. The method includes: receiving sensor values from the stress sensor of the ASIC structure; receiving stress-sensitive sensor information from the MEMS structure; ascertaining stress values of the ASIC structure based on the sensor values of the stress sensor; and correcting the stress-sensitive sensor information of the MEMS structure and generating corrected sensor information based on the stress values of the ASIC structure. A MEMS sensor system is also described.

### CROSS REFERENCE

The present application claims the benefit under 35 U.S.C. § 119 of Germany Patent Application No. DE 10 2025 100 525.7 filed on Jan. 9, 2025, which is expressly incorporated herein by reference in its entirety.

### FIELD

The present invention relates to a method for operating a MEMS sensor system and to a MEMS sensor system.

### BACKGROUND INFORMATION

Certain methods for operating MEMS sensor systems and MEMS sensor systems are described in the related art.

### SUMMARY

It is an object of the present invention to provide an improved method for operating a MEMS sensor system, and an improved MEMS sensor system.

The object may be achieved by the method and the MEMS sensor system having certain features of the present invention. Advantageous embodiments of the present invention are disclosed herein.

According to one aspect of the present invention, a method for operating a MEMS sensor system having at least one ASIC structure, a MEMS structure and a stress sensor formed on the ASIC structure is provided. According to an example embodiment of the present invention, the method comprises:
receiving sensor values from the stress sensor of the ASIC structure;
receiving stress-sensitive sensor information from the MEMS structure;
ascertaining a stress value of the ASIC structure based on the sensor values of the stress sensor and/or ascertaining a stress value of the MEMS structure based on the stress-sensitive sensor information; and
correcting the stress-sensitive sensor information of the MEMS structure and generating corrected sensor information based on the stress value of the ASIC structure and/or based on the stress value of the MEMS structure.

This can achieve a technical advantage that an improved method for operating a MEMS sensor system can be provided. For this purpose, the ASIC structure of the MEMS sensor system comprises at least one stress sensor. Based on the stress sensor, stress values of the ASIC structure can be ascertained.

According to an example embodiment of the present invention, furthermore, stress-sensitive sensor information from the MEMS structure is received. Taking into account the stress values of the ASIC structure ascertained based on the sensor values of the stress sensor, the stress-sensitive sensor information of the MEMS structure can be corrected and corrected sensor information can be ascertained.

The stress values of the stress sensor can thus be used to precisely ascertain the state of the ASIC structure with reference to the stress prevailing in the ASIC structure. This makes precise correction of the sensor information of the MEMS structure possible with respect to the stress prevailing in the ASIC structure. This makes improved operation of the MEMS sensor system possible.

According to one example embodiment of the present invention, the method further comprises the following:
correcting a sensor offset and/or a sensor sensitivity of the MEMS structure based on the corrected stress-sensitive sensor information of the MEMS structure.

This can achieve a technical advantage that corrected sensor offsets and/or sensor sensitivities of the MEMS sensor system can be ascertained based on the corrected sensor information of the MEMS structure. This makes a further improvement in taking into account stress influences on the measurement accuracy of the MEMS sensor system possible.

According to one example embodiment of the present invention, the method further comprises:
ascertaining corrected sensor values of the MEMS sensor system based on the corrected sensor offset and/or the corrected sensor sensitivity of the MEMS structure.

This can achieve a technical advantage that corrected sensor values of the MEMS sensor system can be calculated based on the corrected sensor offset and corrected sensor sensitivity. This makes further improvement of the corrections of stress-related influences on the measurement accuracy of the MEMS sensor system possible.

According to one example embodiment of the present invention, the ASIC structure further comprises a temperature sensor, wherein the method further comprises:
receiving sensor values from the temperature sensor of the ASIC structure;
ascertaining a temperature value of the ASIC structure based on the sensor values of the temperature sensor, wherein ascertaining the stress values of the ASIC structure and/or
correcting sensor information of the MEMS structure is carried out taking into account the temperature value of the ASIC structure.

This can achieve a technical advantage that the temperature sensor can ascertain temperature values of the ASIC structure. The temperature values can also be taken into account in correcting the sensor offset and/or the sensor sensitivity or in correcting the sensor values of the MEMS sensor system.

This allows the sensor values of the MEMS sensor system to be corrected in relation to stress-related influences as well as temperature-related influences. This makes further precision in correcting the measurement accuracy of the MEMS sensor system possible.

According to one example embodiment of the present invention, the MEMS structure further comprises a stress sensor, and the method further comprises:
receiving sensor values from the stress sensor of the MEMS structure;
ascertaining the stress value of the MEMS structure taking into account the sensor values of the stress sensor.

This can achieve a technical advantage that the additional stress sensor formed on the MEMS structure can directly ascertain stress values of the MEMS structure. Such stress values can be taken into account in correcting the sensor information and/or the sensor offset and/or the sensor measurement accuracy and/or the sensor values of the MEMS sensor system according to the stress values of the ASIC structure. This makes further precision of the corrections and thus the measurement accuracy of the MEMS sensor system possible.

According to one example embodiment of the present invention, the MEMS sensor system is designed as a gyroscope sensor system, and/or wherein the stress-sensitive sensor information of the MEMS structure comprises at least one of the following:
frequency information, quadrature information, amplitude/quality factor of a drive.

This can achieve a technical advantage that improved operation of a gyroscope sensor system is made possible. Based on the frequency information, quadrature information and/or information regarding the amplitude or quality factor of the drive of the gyroscope sensor system, a precise ascertainment of the stress values within the MEMS structure can be effected.

According to one aspect of the present invention, a MEMS sensor system is provided having at least one ASIC structure, a MEMS structure and a stress sensor formed on the ASIC structure, wherein the MEMS sensor system is configured to carry out the method for operating a MEMS sensor system according to one of the above-described embodiments of the present invention.

This can achieve a technical advantage that an improved MEMS sensor system can be provided, which is configured to carry out the method according to the present invention for operating a MEMS sensor system having the technical advantages described above.

According to one example embodiment of the present invention, a temperature sensor is formed on the ASIC structure, and/or wherein a stress sensor is formed on the MEMS structure.

This can achieve a technical advantage that direct temperature values of the ASIC structure or stress values of the MEMS structure can be provided by the temperature sensor formed on the ASIC structure and/or the stress sensor formed on the MEMS structure.

According to one aspect of the present invention, a computing unit is provided, which is configured to carry out the method for operating a MEMS sensor system according to one of the above-described embodiments of the present invention.

According to one aspect of the present invention, a computer program product is provided, comprising commands that, when the program is executed by a data processing unit, cause the data processing unit to carry out the method for operating a MEMS sensor system according to one of the above-described embodiments of the present invention.

Example embodiments of the present invention are described with reference to the figures.

### BRIEF DESCRIPTION OF THE DRAWINGS

FIG. 1 is a schematic representation of a MEMS sensor system according to one example embodiment of the present invention.

FIG. 2 is a flowchart of a method for operating a MEMS sensor system according to one example embodiment of the present invention.

FIG. 3 is a further flowchart of the method for operating a MEMS sensor system according to one example embodiment of the present invention.

FIG. 4 is a schematic representation of a computer program product, according to an example embodiment of the present invention.

### DETAILED DESCRIPTION OF EXAMPLE EMBODIMENTS

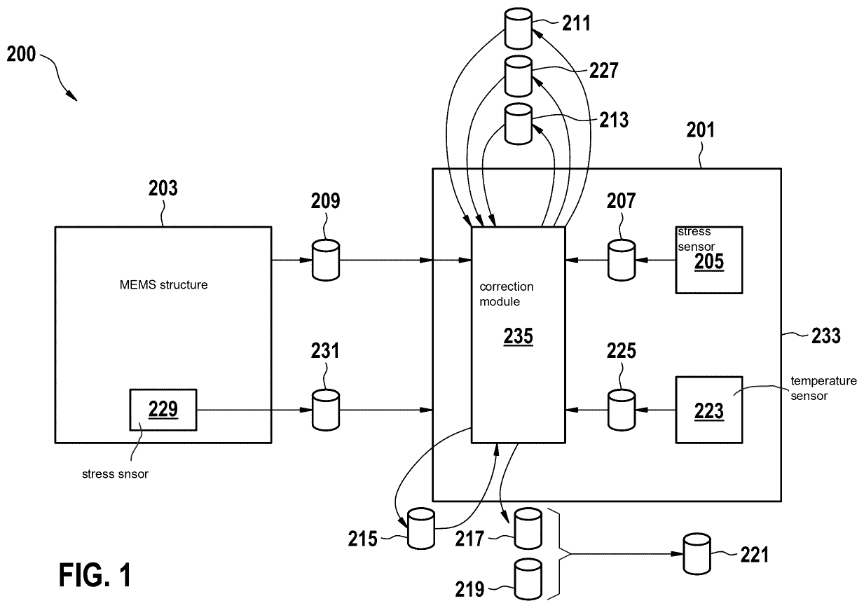

FIG. 1 is a schematic representation of a MEMS sensor system 200 according to one embodiment.

According to the present invention, the MEMS sensor system 200 comprises an ASIC structure 201 and a MEMS structure 203. At least one stress sensor 205 is formed on the ASIC structure 201.

In the embodiment shown, the ASIC structure 201 further comprises a correction module 235.

In order to operate the MEMS sensor system 200, the correction module 235 initially receives sensor values 207 from the stress sensor 205 formed on the ASIC module 201. Furthermore, the correction module 235 comprises stress-sensitive sensor information 209 of the MEMS module 203.

Based on the sensor values 207 of the stress sensor 205, the correction module 235 calculates a stress value 211 of the ASIC structure 201. Here, the stress value 211 describes the stress prevailing in the ASIC structure 201.

Furthermore, stress-sensitive sensor information 209 from the MEMS structure 203 is received. Based on the stress-sensitive sensor information 209, stress values 213 of the MEMS structure 203 can be ascertained. Here, the stress values 213 describe the stress prevailing in the MEMS structure 203.

The stress within the ASIC structure 201 and/or within the MEMS structure 203 can be attributed primarily to external forces acting on the MEMS sensor system 200.

According to one embodiment, the MEMS sensor system 200 is designed as a MEMS gyroscope sensor. Here, the stress-sensitive sensor information 209 provided by the MEMS structure 203 can comprise at least one of the following: frequency information, quadrature information, amplitude/quality factor of a drive of the gyroscope sensor. Based on changes in the provided sensor information, the stress acting on the MEMS structure 203 can be ascertained.

Based on the stress value 211 of the ASIC structure 201 and/or the stress value 213 of the MEMS structure 203, the stress-sensitive sensor information 209 is subsequently corrected and corrected sensor information 215 is generated.

Here, correcting the stress-sensitive sensor information 209 to the stress-related influences of the stress within the ASIC structure 201 and/or the stress within the MEMS structure 203 can be carried out based on correction methods in the related art.

Based on the corrected sensor information 215, a corrected sensor offset 217 and/or a corrected sensor sensitivity 219 are subsequently ascertained according to one embodiment. Here, correcting the sensor offset and/or the sensor sensitivity can in turn be carried out according to correction methods from the related art.

According to one embodiment, based on the corrected sensor offset 217 and/or the corrected sensor sensitivity 219, a correction of the sensor values of the MEMS sensor system 200 is carried out and corrected sensor values 221 are ascertained.

The corrections of the sensor values with respect to the corrected sensor offset 217 and/or the corrected sensor sensitivity 219 can in turn be carried out according to correction methods from the related art.

In the embodiment shown, the ASIC structure 201 further comprises a temperature sensor 223. Based on sensor values 225 of the temperature sensor 223, temperature values 227 of the ASIC structure 201 can be ascertained according to one embodiment.

Here, the temperature values 227 describe a temperature prevailing within the ASIC structure 201. According to one embodiment, the temperature values 227 can be taken into account within the ASIC structure 201 for correcting the stress-sensitive sensor information 209 and/or correcting the sensor offset and/or correcting the sensor sensitivity.

As a result, in addition to the influences of stress within the ASIC structure and/or within the MEMS structure 203, additional negative influences of the temperature within the ASIC structure 201 can be taken into account when correcting the sensor values of the MEMS sensor system 200. This allows for more precise correction of the harmful influences on the measurement accuracy of the MEMS sensor system 200.

In the embodiment shown, the MEMS structure 203 further comprises a stress sensor 229. The stress value 213 of the MEMS structure 203 can be ascertained via sensor values 231 of the stress sensor 229. The stress within the MEMS structure 203 can thus be calculated based on the stress-sensitive sensor information 209 and/or taking into account the sensor values 231 of the stress sensor 229 of the MEMS structure 203.

In the embodiment shown, the ASIC structure 201 is interpreted as a computing unit 233 that is configured to effect the method according to the present invention for operating the MEMS sensor system 200.

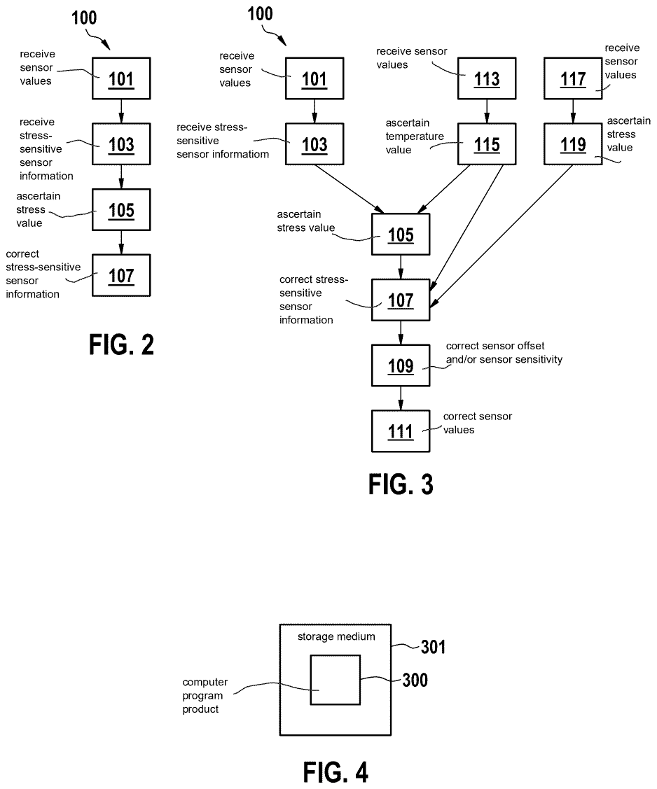

FIG. 2 is a flowchart of a method 100 for operating a MEMS sensor system 200 according to one embodiment.

In order to operate the MEMS sensor system 200, sensor values 207 from the stress sensor 205 of the ASIC structure 201 are initially received in a first method step 101.

In a further method step 103, the stress-sensitive sensor information 209 from the MEMS structure 203 is received.

In a further method step 105, the stress value 211 of the ASIC structure 201 is ascertained based on the sensor values 207 of the stress sensor 205.

Alternatively or additionally, the stress value 213 of the MEMS structure 203 is ascertained based on the stress-sensitive sensor information 209.

In a further method step 107, the stress-sensitive sensor information 209 is corrected based on the stress value 211 of the ASIC structure 201 and/or the stress value 213 of the MEMS structure 203, and corrected sensor information 215 is generated.

FIG. 3 is a further flowchart of the method 100 for operating a MEMS sensor system 200 according to one embodiment.

The embodiment in FIG. 3 is based on the embodiment in FIG. 2 and comprises all the method steps described there. In the embodiment shown, sensor values 225 from the temperature sensor 223 of the ASIC structure 201 are also received in a method step 113.

In a further method step 115, the temperature value 227 of the ASIC structure 201 is ascertained.

In a further method step 117, the sensor values 231 from the stress sensor 229 of the MEMS structure 203 are received.

In a method step 119, the stress value 213 is ascertained taking into account the sensor values 231 of the stress sensor 229 of the MEMS structure 203.

Here, the temperature values 227 of the ASIC structure 201 can be used to ascertain the stress value 211 of the ASIC structure 201.

In addition, the temperature values 227 of the ASIC structure 201 and the sensor values of the stress sensor 229 of the MEMS structure 203 can be incorporated into correcting the stress-sensitive sensor information 209 and generating the corrected sensor information 215.

In the embodiment shown, in a further method step 109, the sensor offset and/or the sensor sensitivity are corrected based on the corrected sensor information 215, and the corrected sensor offset 217 and/or the corrected sensor sensitivity 219 are generated.

In a further method step 111, the sensor values of the MEMS sensor system 200 are corrected based on the corrected sensor offset 217 and/or the corrected sensor sensitivity 219, and the corrected sensor values 221 of the MEMS sensor system 200 are ascertained.

FIG. 4 is a schematic representation of a computer program product 300 comprising commands that, when the program is executed by a data processing unit, cause the unit to carry out the method 100 for operating a MEMS sensor system 200.

In the embodiment shown, the computer program product 300 is stored on a storage medium 301. Here, the storage medium 301 can be any storage medium from the related art.

What is claimed is:

1. A method for operating a MEMS sensor system, the MEMS sensor system including an ASIC structure, a MEMS structure, and a stress sensor formed on the ASIC structure, the method comprising the following steps:
receiving sensor values from the stress sensor of the ASIC structure;
receiving stress-sensitive sensor information from the MEMS structure;
ascertaining a stress value of the ASIC structure based on the sensor values of the stress sensor and/or ascertaining a stress value of the MEMS structure based on the stress-sensitive sensor information; and
correcting the stress-sensitive sensor information of the MEMS structure and generating corrected sensor information based on the stress value of the ASIC structure and/or based on the stress value of the MEMS structure.

2. The method according to claim 1, further comprising:
correcting a sensor offset and/or a sensor sensitivity and generating a corrected sensor offset and/or a corrected sensor sensitivity of the MEMS structure based on the corrected stress-sensitive sensor information of the MEMS structure.

3. The method according to claim 2, further comprising:
ascertaining corrected sensor values of the MEMS sensor system based on the corrected sensor offset and/or the corrected sensor sensitivity of the MEMS structure.

4. The method according to claim 1, wherein the ASIC structure further includes a temperature sensor, and wherein the method further comprises:
receiving sensor values from the temperature sensor of the ASIC structure;
ascertaining a temperature value of the ASIC structure based on the sensor values of the temperature sensor;
wherein the ascertaining of the stress value of the ASIC structure and/or the correcting of the stress-senstive sensor information of the MEMS structure is carried out taking into account the temperature value of the ASIC structure.

5. The method according to claim 1, wherein the MEMS structure further includes a stress sensor, and wherein the method further comprises:
receiving sensor values from the stress sensor of the MEMS structure;
ascertaining the stress value of the MEMS structure taking into account the sensor values of the stress sensor of the stress sensor of the MEMS structure.

6. The method according to claim 1, wherein: (i) the MEMS sensor system is a gyroscope sensor system, and/or (ii) the stress-sensitive sensor information of the MEMS structure includes at least one of the following: frequency information of a drive, quadrature information of the drive, amplitude/quality factor of the drive.

7. A MEMS sensor system having at least one ASIC structure, a MEMS structure, and a stress sensor formed on the ASIC structure, wherein the MEMS sensor system is configured to perform the following steps comprising:
receiving sensor values from the stress sensor of the ASIC structure;
receiving stress-sensitive sensor information from the MEMS structure;
ascertaining a stress value of the ASIC structure based on the sensor values of the stress sensor and/or ascertaining a stress value of the MEMS structure based on the stress-sensitive sensor information; and
correcting the stress-sensitive sensor information of the MEMS structure and generating corrected sensor information based on the stress value of the ASIC structure and/or based on the stress value of the MEMS structure.

8. The MEMS sensor system according to claim 7, wherein: (i) a temperature sensor is formed on the ASIC structure, and/or (ii) a stress sensor is formed on the MEMS structure.

9. A system, comprising:
a computing unit configured to carry out a method for operating a MEMS sensor system, the MEMS sensor system including an ASIC structure, a MEMS structure, and a stress sensor formed on the ASIC structure, the method including the following steps:
receiving sensor values from the stress sensor of the ASIC structure;
receiving stress-sensitive sensor information from the MEMS structure;
ascertaining a stress value of the ASIC structure based on the sensor values of the stress sensor and/or ascertaining a stress value of the MEMS structure based on the stress-sensitive sensor information; and
correcting the stress-sensitive sensor information of the MEMS structure and generating corrected sensor information based on the stress value of the ASIC structure and/or based on the stress value of the MEMS structure.

10. A non-transitory computer-readable medium on which is stored a computer program including commands for operating a MEMS sensor system, the MEMS sensor system including an ASIC structure, a MEMS structure, and a stress sensor formed on the ASIC structure, the commands, when executed by a data processor, causing the data processor to perform the following steps:
receiving sensor values from the stress sensor of the ASIC structure;
receiving stress-sensitive sensor information from the MEMS structure;
ascertaining a stress value of the ASIC structure based on the sensor values of the stress sensor and/or ascertaining a stress value of the MEMS structure based on the stress-sensitive sensor information; and
correcting the stress-sensitive sensor information of the MEMS structure and generating corrected sensor information based on the stress value of the ASIC structure and/or based on the stress value of the MEMS structure.
